(19) United States
(12) Patent Application Publication
(10) Pub. No.: US 2023/0408244 A1
(43) Pub. Date: Dec. 21, 2023

(54) LAMINATED FILM, METHOD FOR PRODUCING SECOND LAMINATED FILM, AND METHOD FOR PRODUCING STRAIN SENSOR

(71) Applicant: NITTO DENKO CORPORATION, Ibaraki-shi, Osaka (JP)

(72) Inventors: Toshimasa NISHIMORI, Ibaraki-shi, Osaka (JP); Kazuhiro NAKAJIMA, Ibaraki-shi, Osaka (JP); Tomotake NASHIKI, Ibaraki-shi, Osaka (JP); Eiji NIWA, Tomiya-shi, Miyagi (JP)

(21) Appl. No.: 18/251,270

(22) PCT Filed: Oct. 28, 2021
(86) PCT No.: PCT/JP2021/039823

§ 371 Date: May 1, 2023

(30) Foreign Application Priority Data
Oct. 30, 2020 (JP) 2020-182131

(51) Int. Cl. G01B 7/16; C23C 14/06; C23C 14/34; C23C 14/58

(52) U.S. Cl. CPC G01B 7/18; C23C 14/5873; C23C 14/34; C23C 14/0641

(57) ABSTRACT

A laminated film includes an insulating substrate resin film and a resistance layer in order in a thickness direction. The resistance layer includes chromium nitride. A temperature coefficient of resistance of the resistance layer is −400 ppm/° C. or more and −200 ppm/° C. or less.

### TECHNICAL FIELD

The present invention relates to a laminated film, a method for producing a second laminated film, and a method for producing a strain sensor, specifically, to a laminated film, a method for producing a second laminated film using the laminated film, and a method for producing a strain sensor using the laminated film.

### BACKGROUND ART

Conventionally, a strain sensor including an insulating substrate, and a patterned Cr—N thin film disposed on its surface has been known (ref: for example, Patent Document 1 below).

In Patent Document 1, first, a thin film laminated film is fabricated by forming the Cr—N thin film on the surface of the insulating substrate to be then heat-treated at 300° C., and the Cr—N thin film is patterned, thereby producing the strain sensor. In Patent Document 1, by the heat treatment at 300° C., an absolute value of a temperature coefficient of resistance (TCR) of the Cr—N thin film is reduced, thereby improving the stability of the strain sensor.

Further, as the insulating substrate capable of withstanding the above-described high-temperature heat treatment, a hard silicon substrate is used.

### CITATION LIST

### Patent Document

Patent Document 1: Japanese Unexamined Patent Publication No. 2015-31633

### SUMMARY OF THE INVENTION

### Problem to be Solved by the Invention

However, a substrate made of a resin having low heat resistance may be desired to be used in accordance with its application and purpose. However, it is impossible to heat-treat the substrate made of such a resin at the above-described temperature, and the absolute value of the temperature coefficient of resistance may not be reduced.

The present invention provides a laminated film capable of forming a resistance layer having a low absolute value of a temperature coefficient of resistance even when heated at a low temperature, a method for producing a second laminated film using the laminated film, and a method for producing a strain sensor using the laminated film.

### Means for Solving the Problem

The present invention [1] includes a laminated film including an insulating substrate resin film and a resistance layer in order in a thickness direction, wherein the resistance layer includes chromium nitride, and a temperature coefficient of resistance of the resistance layer is −400 ppm/° C. or more and −200 ppm/° C. or less.

The present invention [2] includes the laminated film described in the above-described [1], wherein the resistance layer has a body-centered cubic lattice structure.

The present invention [3] includes the laminated film described in the above-described [1] or [2], wherein the resistance layer does not have a A15-type structure.

The present invention [4] includes the laminated film described in any one of the above-described [1] to [3], wherein parts by mole of nitrogen atoms with respect to 100 parts by mole of chromium atoms is 3.0 parts by mole or more and below 9 parts by mole in the chromium nitride.

The present invention [5] includes the laminated film described in any one of the above-described [1] to [4], wherein a thickness of the resistance layer is 10 nm or more and 150 nm or less.

The present invention [6] includes the laminated film described in any one of the above-described [1] to [5], wherein a thickness of the substrate resin film is 10 μm or more and 200 μm or less.

The present invention [7] includes the laminated film described in any one of the above-described [1] to [6], wherein a material for the substrate resin film is polyimide.

The present invention [8] includes a method for producing a second laminated film including a preparation step of preparing the laminated film described in any one of the above-described [1] to [7] and a heating step of heating the laminated film at 200° C. or less.

The present invention [9] includes the method for producing a second laminated film described in the above-described [8], wherein in the heating step, a temperature coefficient of resistance of the resistance layer after heating is set at −100 ppm/° C. or more and 100 ppm/° C. or less.

The present invention [10] includes a method for producing a strain sensor including a preparation step of preparing the laminated film described in any one of the above-described [1] to [7], a heating step of heating the laminated film at 200° C. or less, and a patterning step of patterning the resistance layer in the laminated film.

### Effect of the Invention

The laminated film of the present invention includes a resistance layer having a predetermined temperature coefficient of resistance. Therefore, even when the laminated film is heated at a low temperature, it is possible to form a resistance layer having a low absolute value of the temperature coefficient of resistance.

The method for producing a second laminated film of the present invention produces a second laminated film using the laminated film of the present invention. Therefore, even when heated at a low temperature, it is possible to form a resistance layer having a low absolute value of the temperature coefficient of resistance.

The method for producing a strain sensor of the present invention produces a strain sensor using the laminated film of the present invention. Therefore, it is possible to obtain a strain sensor having excellent stability.

### BRIEF DESCRIPTION OF THE DRAWINGS

FIG. 1 shows a cross-sectional view of one embodiment of a laminated film of the present invention.

FIGS. 2A and 2B show strain sensors obtained by patterning a resistance layer shown in FIG. 1:

FIG. 2A illustrating a cross-sectional view and

FIG. 2B illustrating a plan view.

### DESCRIPTION OF EMBODIMENTS

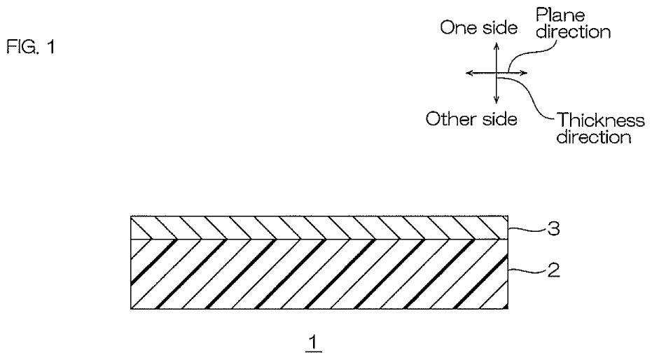

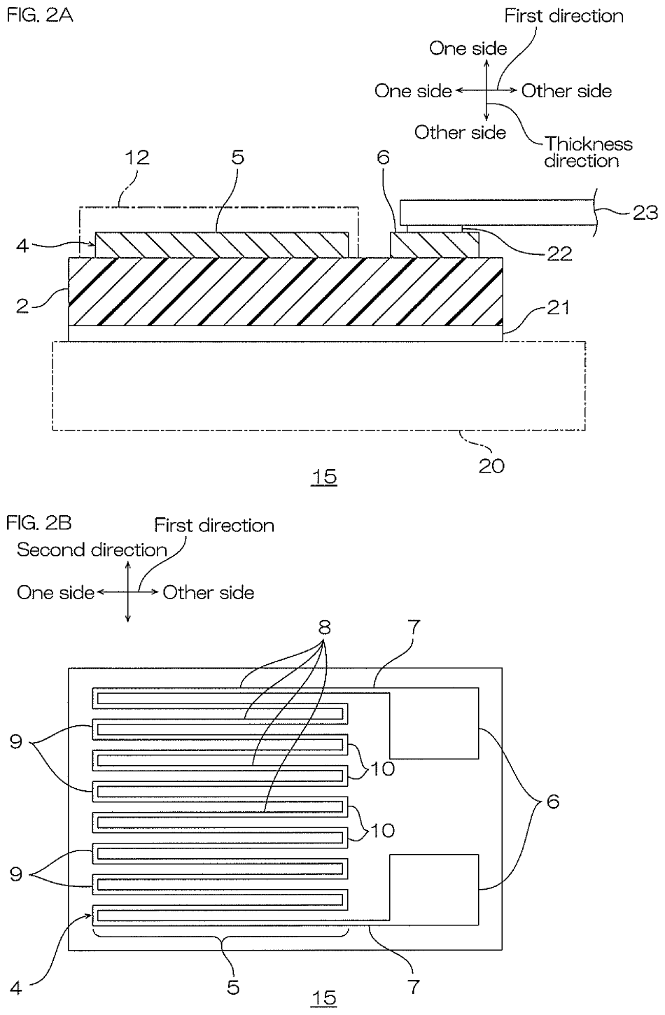

One embodiment of a laminated film and a strain sensor of the present invention is described with reference to FIGS. 1 to 2B.

[Laminated Film]

A laminated film 1 is used in the production of a second laminated film to be described later and a strain sensor 15 to be described later (ref. FIGS. 2A to 2B).

The laminated film 1 is distributed alone as a precursor of the second laminated film and the strain sensor 15.

The laminated film 1 has a flat plate shape extending in a plane direction perpendicular to a thickness direction. Specifically, the laminated film 1 includes a substrate resin film 2 and a resistance layer 3 in order toward one side in the thickness direction. Specifically, the laminated film 1 includes the substrate resin film 2 and the resistance layer 3 disposed on one surface of the substrate resin film 2.

[Substrate Resin Film]

The substrate resin film 2 has insulating properties. The substrate resin film 2 forms the other surface in the thickness direction of the laminated film 1. The substrate resin film 2 has a flat plate shape extending in the plane direction.

Examples of a material for the substrate resin film include resins such as polyimide, polyester, polyethylene terephthalate, and polyethylene naphthalate. As the material for the substrate resin film 2, preferably, polyimide is used. When the substrate resin film 2 is polyimide, it can be heated to 200° C.

A linear expansion coefficient of the substrate resin film 2 is, for example, 30 ppm/° C. or less, preferably 15 ppm/° C. or less.

The thickness of the substrate resin film 2 is not particularly limited, and is, for example, 2 m or more, from the viewpoint of suppressing the occurrence of wrinkles, preferably 10 μm or more, more preferably 20 μm or more, and for example, 500 μm or less, preferably 300 μm or less, from the viewpoint of conveyance in a roll-to-roll manner, more preferably 200 μm or less.

One surface in the thickness direction of the substrate resin film 2 may be, for example, subjected to treatment such as corona discharge treatment, ultraviolet irradiation treatment, plasma treatment, and sputter etching treatment for improving the adhesion to the resistance layer 3.

The number of substrate resin films 2 in the laminated film 1 is not particularly limited, and is preferably 1.

[Resistance Layer]

The resistance layer 3 is a layer which is heated, and is also patterned when the strain sensor 15 (ref. FIGS. 2A to 2B) is produced from the laminated film 1.

The resistance layer 3 is disposed on one surface in the thickness direction of the substrate resin film 2. The resistance layer 3 forms one surface in the thickness direction of the laminated film 1. Specifically, the resistance layer 3 is in contact with the entire one surface in the thickness direction of the substrate resin film 2.

The resistance layer 3 includes chromium nitride. Specifically, the material for the resistance layer 3 contains chromium nitride as a main component. On the other hand, for example, the material for the resistance layer 3 is allowed to be mixed with inevitable impurities. A ratio of the inevitable impurities in the resistance layer 3 is, for example, 1 atom % or less, preferably 0.1 atom % or less, more preferably 0.05 atom % or less. Preferably, the resistance layer 3 is made of chromium nitride.

In chromium nitride, parts by mole of nitrogen atoms with respect to 100 parts by mole of chromium atoms is, for example, 3.0 parts by mole or more, preferably 3.5 parts by mole or more, and for example, 10 parts by mole or less, preferably below 9.0 parts by mole, more preferably 8.0 parts by mole or less, further more preferably 6.0 parts by mole or less.

When the above-described parts by mole is the above-described lower limit or more, it is possible to adjust a temperature coefficient of resistance of the resistance layer 3 (more specifically, the temperature coefficient of resistance before heating, described later) within a predetermined range to be described later.

When the above-described parts by mole is the above-described upper limit or less, it is possible to adjust the temperature coefficient of resistance of the resistance layer 3 (more specifically, the temperature coefficient of resistance before heating, described later) within a predetermined range to be described later.

A method for determining the above-described parts by mole is described in detail in Examples to be described later.

Further, the resistance layer 3, as a crystalline structure of chromium nitride, does not include a A15 structure, and has a body-centered cubic lattice structure.

When the resistance layer 3 has the body-centered cubic lattice structure, it is possible to adjust the temperature coefficient of resistance of the resistance layer 3 (more specifically, the temperature coefficient of resistance before heating, described later) within a predetermined range to be described later.

When the resistance layer 3 does not include the A15 structure, in a heating step to be described later, it is possible to improve the stability by increasing the crystallinity of the resistance layer 3 without heating at a high temperature.

The method for measuring the crystal structure of the resistance layer 3 is described in detail in Examples to be described later.

Then, the temperature coefficient of resistance of the resistance layer 3 (more specifically, the temperature coefficient of resistance before heating) is −400 ppm/° C. or more, preferably, −300 ppm/° C. or more, and −200 ppm/° C. or less.

When the above-described temperature coefficient of resistance is the above-described lower limit or more, it is possible to lower an absolute value of the temperature coefficient of resistance (more specifically, the temperature coefficient of resistance after heating) even when the resistance layer 3 is heated at a low temperature. Therefore, it is possible to obtain the strain sensor 15 having excellent stability.

On the other hand, when the above-described temperature coefficient of resistance is below the above-described lower limit, it is impossible to lower the absolute value of the temperature coefficient of resistance (more specifically, the temperature coefficient of resistance after heating) even when the resistance layer 3 is heated at a low temperature. Therefore, it is impossible to obtain the strain sensor 15 having the excellent stability.

Further, when the above-described temperature coefficient of resistance is the above-described upper limit or less, it is possible to lower the absolute value of the temperature coefficient of resistance (more specifically, the temperature coefficient of resistance after heating) even when the resistance layer 3 is heated at a low temperature. Therefore, it is possible to obtain the strain sensor 15 having the excellent stability.

On the other hand, when the above-described temperature coefficient of resistance is above the above-described upper limit, it is impossible to lower the absolute value of the temperature coefficient of resistance (more specifically, the temperature coefficient of resistance after heating) even when the resistance layer 3 is heated at a low temperature. Therefore, it is impossible to obtain the strain sensor 15 having the excellent stability.

The method for determining the temperature coefficient of resistance of the resistance layer 3 is described in detail in Examples to be described later.

The thickness of the resistance layer 3 is, for example, 5 nm or more, from the viewpoint of increasing a gauge ratio of the resistance layer 3, preferably 10 nm or more, and, for example, from the viewpoint of suppressing the occurrence of cracks of the resistance layer 3, 150 nm or less, preferably 120 nm or less.

The number of resistance layers 3 in the laminated film 1 is, for example, not particularly limited, and is preferably 1. Specifically, the number of resistance layers 3 with respect to the one substrate resin film 2 is preferably 1.

[Method for Producing Laminated Film]

In the method for producing the laminated film 1, for example, the laminated film 1 is formed in a roll-to-roll method.

For example, the resistance layer 3 is film-formed on one surface in the thickness direction of the substrate resin film 2, while the long substrate resin film 2 is conveyed. Examples of a film forming method include sputtering methods, vacuum evaporation methods, and ion plating methods. Preferably, a sputtering method is used, more preferably, a reactive sputtering is used.

In the reactive sputtering, the target is made of chromium, and as a sputtering gas, a mixed gas of an inert gas such as argon with nitrogen is used. The number of parts by volume of nitrogen with respect to 100 parts by volume of the inert gas is, for example, 0.5 parts by volume or more, and 15 parts by volume or less.

Thus, the laminated film 1 including the substrate resin film 2 and the resistance layer 3 is fabricated.

Then, the laminated film 1 can be preferably used in the production of the second laminated film and the strain sensor.

[Method for Producing Second Laminated Film]

The second laminated film is obtained by heating the laminated film 1 (more specifically, the resistance layer 3 in the laminated film 1). That is, the second laminated film is the laminated film 1 after heating.

Specifically, the method for producing the second laminated film includes a preparation step of preparing the laminated film 1, and a heating step of heating the laminated film 1 at a predetermined temperature.

In the preparation step, the laminated film 1 is prepared.

In the heating step, the laminated film 1 (the resistance layer 3) is heated in order to improve the stability by increasing the crystallinity of the resistance layer 3.

As heating conditions, a heating temperature is the temperature at which the substrate resin film 2 is not damaged by heating, and is, for example, 200° C. or less, preferably 160° C. or less, and for example, 80° C. or more, preferably 100° C. or more, more preferably 120° C. or more. The heating time is, for example, 20 minutes or more, preferably 50 minutes or more, and for example, 240 minutes or less, preferably 120 minutes or less.

When the heating temperature is the above-described upper limit or less, it is possible to suppress the damage to the substrate resin film 2 by heating.

It is possible to reduce the absolute value of the temperature coefficient of resistance of the resistance layer 3 after heating by the above-described heating.

Specifically, as described above, since the temperature coefficient of resistance of the resistance layer 3 before heating is within a predetermined range, it is possible to reduce the absolute value of the temperature coefficient of resistance of the resistance layer 3 after heating.

Specifically, the temperature coefficient of resistance of the resistance layer 3 after heating is, for example, −100 ppm/° C. or more, preferably −80 ppm/° C. or more, more preferably −50 ppm/° C. or more, further more preferably −20 ppm/° C. or more, and for example, 100 ppm/° C. or less, preferably 80 ppm/° C. or less, more preferably 50 ppm/° C. or less, further more preferably 20 ppm/° C. or less.

That is, the absolute value of the temperature coefficient of resistance of the resistance layer 3 after heating is, for example, 100 or less, preferably 80 or less, more preferably 50 or less, further more preferably 20 or less.

When the absolute value of the temperature coefficient of resistance is the above-described upper limit or less, the second laminated film has the excellent stability.

[Method for Producing Strain Sensor]

The method for producing the strain sensor 15 includes a preparation step of preparing the laminated film 1, a heating step of heating the laminated film 1 at a predetermined temperature, and a patterning step of patterning the resistance layer 3 in the laminated film 1.

In the preparation step, the laminated film 1 is prepared.

In the heating step, the laminated film 1 (the resistance layer 3) is heated in order to improve the stability by increasing the crystallinity of the resistance layer 3.

The heating conditions are the same as those in the heating step of the method for producing the second laminated film as described above. The heating temperature is the temperature at which the substrate resin film 2 is not damaged by heating, and is, for example, 200° C. or less, preferably, 160° C. or less, and for example, 80° C. or more, preferably 100° C. or more, more preferably 120° C. or more. The heating time is, for example, 20 minutes or more, preferably 50 minutes or more, and for example, 240 minutes or less, preferably 120 minutes or less.

When the heating temperature is the above-described upper limit or less, it is possible to suppress the damage to the substrate resin film 2 by heating.

It is possible to reduce the absolute value of the temperature coefficient of resistance of the resistance layer 3 after heating by the above-described heating.

Specifically, as described above, since the temperature coefficient of resistance of the resistance layer 3 before heating is within a predetermined range, it is possible to reduce the absolute value of the temperature coefficient of resistance of the resistance layer 3 after heating.

Specifically, the temperature coefficient of resistance of the resistance layer 3 after heating is, for example, −100 ppm/° C. or more, preferably −80 ppm/° C. or more, more preferably −50 ppm/° C. or more, further more preferably −20 ppm/° C. or more, and for example, 100 ppm/° C. or less, preferably 80 ppm/° C. or less, more preferably 50 ppm/° C. or less, further more preferably 20 ppm/° C. or less.

That is, the absolute value of the temperature coefficient of resistance of the resistance layer 3 after heating is, for example, 100 or less, preferably 80 or less, more preferably 50 or less, further more preferably 20 or less.

When the absolute value of the temperature coefficient of resistance is the above-described upper limit or less, the strain sensor 15 has the excellent stability.

Next, in the patterning step, as shown in FIG. 2A, the resistance layer 3 in the laminated film 1 is patterned, thereby forming the resistance pattern 4. As the patterning of the resistance layer 3, for example, etching is used, and specifically, dry etching and wet etching are used, preferably, dry etching is used, more preferably, laser etching is used.

The resistance pattern 4 integrally includes a strain sensor portion 5, a terminal 6, and a wiring 7.

As shown in FIG. 2B, the strain sensor portion 5 has a generally zigzag shape when viewed from the top. Specifically, the strain sensor portion 5 has a plurality of first wirings 8, a plurality of first connecting wirings 9, and a plurality of second connecting wirings 10.

Each of the plurality of first wirings 8 extends along a first direction (direction included in the plane direction). The plurality of first wirings 8 are disposed in alignment at intervals in a second direction (direction included in the plane direction, and direction perpendicular to the first direction).

The plurality of first connecting wirings 9 communicate one end portions in the first direction of the first wirings 8 adjacent to each other in the second direction.

The plurality of second connecting wirings 10 communicate the other end portions in the first direction of the first wirings 8 adjacent to each other in the second direction. When projected in the first direction, the first connecting wiring 9 and the second connecting wiring 10 are alternately disposed.

The terminal 6 is spaced from the strain sensor portion 5 in the plane direction. The terminal 6 has, for example, a generally rectangular land shape when viewed from the top. The two terminals 6 are provided at spaced intervals from each other.

The wirings 7 communicate the two terminals 6 with both ends of the strain sensor portion 5.

In the strain sensor portion 5, one electrically conductive path which passes through one wiring 7, the strain sensor portion 5, and the other wiring 7 from one terminal 6 to eventually reach the other terminal 6 is formed.

A dimension of the strain sensor portion 5 is appropriately set in accordance with its application and purpose. A width of the first wiring 8, the first connecting wiring 9, and the second connecting wiring 10 is, for example, 1 μm or more, preferably 5 μm or more, more preferably 10 μm or more, and for example, 150 μm or less, preferably 100 μm or less, more preferably 70 μm or less.

The shape of the substrate resin film 2 is also appropriately set in accordance with the application and purpose of the strain sensor 15, and is formed into a desired dimension by, for example, outer shape processing.

Next, the method for measuring a strain amount (deformation amount) of a test object 20 by disposing the strain sensor 15 in the test object 20 is described.

As shown in FIG. 2A, the laminated film 1 of the strain sensor 15 is attached to the surface of the test object 20 through an adhesive layer 21. Further, lead wirings 23 are connected to the two terminals 6 through electrically conductive adhesive layers 22. The lead wirings 23 are electrically connected to an external resistance measuring circuit (not shown).

When the test object 20 is deformed, the resistance value of the strain sensor portion 5 changes. The strain amount is calculated in the resistance measuring circuit based on this.

Specifically, when the test object 20 is expanded in the first direction, tensile strain is applied to the first wiring 8, the cross-sectional area of the first wiring 8 is reduced, and the resistance of the strain sensor portion 5 is increased. On the other hand, when the test object 20 is contracted, compressive strain is applied to the first wiring 8, the cross-sectional area of the first wiring 8 is increased, and the resistance of the strain sensor portion 5 is reduced. The strain amount of the test object 20 is calculated from such a resistance change amount.

### Function and Effect of One Embodiment

The laminated film 1 includes the resistance layer 3 having a predetermined temperature coefficient of resistance. Therefore, even when the laminated film is heated at a low temperature, it is possible to form the resistance layer having the low absolute value of the temperature coefficient of resistance. Therefore, it is possible to obtain the strain sensor 15 having the excellent stability.

The method for producing the second laminated film produces the second laminated film using the laminated film 1. Therefore, even when heated at a low temperature, it is possible to form the resistance layer 3 having the low absolute value of the temperature coefficient of resistance. Therefore, it is possible to obtain the strain sensor 15 having the excellent stability.

The method for producing the strain sensor 15 produces the strain sensor 15 using the laminated film 1. Therefore, it is possible to obtain the strain sensor 15 having the excellent stability.

### Modified Examples

In each modified example below, the same reference numerals are provided for members and steps corresponding to each of those in the above-described one embodiment, and their detailed description is omitted. Further, each modified example can achieve the same function and effect as that of one embodiment unless otherwise specified. Furthermore, one embodiment and each modified example can be appropriately used in combination.

In one embodiment, the timing of the heating is before the patterning of the resistance layer 3, and the timing may be also, for example, after the patterning of the resistance layer 3.

The substrate resin film 2 may, for example, include a functional layer (not shown) such as a hard coat layer, an easy adhesive layer, and an antistatic layer on one surface thereof in the thickness direction.

Further, the strain sensor 15 may further include a cover layer 12 which covers the strain sensor portion 5 and made of resin (one-dotted chain line).

In one embodiment, as the preferable number of the resistance layer 3 in the laminated film 1, 1 is illustrated. Alternatively, for example, though not shown, the number may be 2. In this case, each of the two resistance layers 3 is disposed on each of both sides in the thickness direction of the substrate resin film 2. In other words, in a preferable example of the modified example, the number of resistance layers 3 with respect to the one substrate resin film 2 is preferably 2.

### EXAMPLES

Next, the present invention is further more specifically described based on Examples and Comparative Examples. The present invention is however not limited by Examples and Comparative Examples. The specific numerical values in mixing ratio (content ratio), property value, and parameter used in the following description can be replaced with upper limit values (numerical values defined as “or less” or “below”) or lower limit values (numerical values defined as “or more” or “above”) of corresponding numerical values in mixing ratio (content ratio), property value, and parameter described in the above-described “DESCRIPTION OF EMBODIMENTS”.

### Example 1

The substrate resin film 2 having a thickness of 38 μm and made of polyimide having a linear expansion coefficient of 13 ppm/° C. was prepared.

The substrate resin film 2 was set in a feed roll and a winding roll of a roll-to-roll, and set in a sputtering device disposed therebetween.

Subsequently, after evacuating the sputtering device until a degree of vacuum was 1×10⁻¹ Pa or less, the resistance layer 3 made of chromium nitride was film-formed under the following conditions by a reactive pulsed DC sputtering (pulse width: 1 s, frequency: 100 kHz). A target was made of metal chromium.
Target: metal chromium, flat plate shape having 500 mmx 150 mm
Power: 5 kW (power density: 6.7 W/cm²)
Magnetic flux density (target surface): 30 mT to 100 mT
Substrate temperature: 150° C.
Sputtering gas: mixed gas of argon and nitrogen
Film deposition pressure: 0.085 Pa

A ratio of the nitrogen gas was adjusted so that the ratio of the number of moles of nitrogen atoms to the number of moles of chromium atoms was as shown in Table 1.

Thus, the laminated film 1 including the substrate resin film 2 and the resistance layer 3 was produced.

Next, the laminated film 1 was heated at 130° C. for 60 minutes.

Thereafter, the laminated film 1 was cut into a size of 10 mmx 200 mm, and the resistance pattern 4 consisting of the zigzag-shaped strain sensor portion 5, the terminal 6, and the wiring 7 was formed from the resistance layer 3 by laser patterning. A line width of the strain sensor portion 5 was 30 m. At this time, it was adjusted so that the resistance of the resistance pattern 4 was about 10 kΩ, and the resistance of the strain sensor portion 5 was 30 times as large as the resistance of the wiring 7. Thus, the strain sensor 15 was obtained.

### Examples 2 to 6 and Comparative Examples 1 to 6

The laminated film 1, and further, the strain sensor 15 were obtained in the same manner as in Example 1, except that a ratio of the number of moles of nitrogen atoms to the number of moles of chromium atoms, and the heating conditions were changed in accordance with Table 1. Specifically, a ratio of nitrogen in the sputtering gas was adjusted.

(Evaluation)

The following items were evaluated. The results are described in Table 1.

<Temperature Coefficient of Resistance>

The temperature of the resistance layer 3 of each of the laminated films 1, and the strain sensor portion 5 of each of the strain sensors 15 of Examples and Comparative Examples was set at 5° C. A tester was connected to each of the two terminals 6, and the two-terminal resistance at 5° C. was measured by applying a constant current and reading the voltage. The two-terminal resistance at 25° C. and 45° C. was also measured in the same manner.

Then, an average value of the temperature coefficient of resistance calculated from the resistance value at 5° C. and 25° C., and the temperature coefficient of resistance calculated from the resistance value at 25° C. and 45° C. was determined as the temperature coefficient of resistance of the resistance layer 3 of the laminated film 1 (temperature coefficient of resistance of the resistance layer 3 before heating) and the temperature coefficient of resistance of the strain sensor portion 5 (temperature coefficient of resistance of the resistance layer 3 after heating).

In Examples 1, 2, and 4, the temperature coefficient of resistance of the resistance layer 3 before heating is different, while the ratio of nitrogen atoms to chromium atoms is the same. Specifically, the temperature coefficient of resistance of the resistance layer 3 before heating has variation of about ±16.

Such variation is due to the measurement error of the resistance value, and variation in the plane of the resistance layer 3. Such variation is to the extent that does not interfere the effect of the present invention.

The same applies to Examples 3 and 4.

<Ratio of Nitrogen Atoms>

As for the resistance layer 3 of each of the laminated films 1 of Examples and Comparative Examples, the ratio of nitrogen atoms to chromium atoms was measured based on the following conditions by Rutherford backscattering spectrometry (RBS).

(Measurement Conditions)
Equipment: Pelletron 3SDH, manufactured by National Electrostatics Corporation Measurement Conditions:
Incident ion: ⁴He⁺⁺
Incident energy: 2300 keV
Incident angle: 0 deg
Scattering angle: 160 deg
Sample current: 4 nA
Beam diameter: 2 mmΦ
In-plane rotation: none
Amount of irradiation: 40 μC

<Crystal Structure of Resistance Layer of Laminated Film>

As for the resistance layer 3 of each of the laminated films 1 of Examples and Comparative Examples, the crystal structure of the resistance layer 3 of the laminated film 1 was measured by X-ray diffraction.

As for Examples 1 to 6, no peak around 39 degrees originated from the A15 structure was observed, and a peak around 43.8 degrees originated from the body-centered cubic lattice structure was observed.

In other words, it is found that the resistance layers 3 of Examples 1 to 6 do not have the A15 structure, and have only the body-centered cubic lattice structure.

TABLE 1

Parts by Mole of
Nitrogen Atoms

| | |
|---|---|
| to 100 Parts by | Temperature Coefficient of |
| Mole of | Resistance (ppm/° C.) |

| | Chromium | Heating | | Temperature | Temperature |
|---|---|---|---|---|---|
| Ex. | Atoms | Conditions | | Coefficient of | Coefficient of |
| Comparative | (Parts by | Temperature | Time | Resistance | Resistance |

| Ex. No. | Mole) | (° C.) | (Hours) | Before Heating | After Heating |
|---|---|---|---|---|---|
| Ex. 1 | 4.4 | 135 | 1 | −230.7 | −94.6 |
| Ex. 2 | 4.4 | 155 | 1 | −246.3 | −19.3 |
| Ex. 3 | 4 | 180 | 1 | −218.1 | 99.2 |
| Ex. 4 | 4 | 155 | 0.5 | −212.3 | −75.3 |
| Ex. 5 | 4.4 | 155 | 3 | −232.7 | 43.6 |
| Ex. 6 | 8.4 | 155 | 1 | −383.6 | −46.5 |
| Comparative | 15 | 155 | 1 | −712.3 | −405 |
| Ex. 1 | | | | | |
| Comparative | 9 | 155 | 1 | −423.8 | −116.4 |
| Ex. 2 | | | | | |
| Comparative | 2.9 | 155 | 1 | −170 | 150.4 |
| Ex. 3 | | | | | |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The laminated film, the method for producing a second laminated film, and the method for producing a strain sensor of the present invention can be, for example, preferably used in the production of a strain sensor.

### DESCRIPTION OF REFERENCE NUMERALS

1 Laminated film
2 Substrate resin film
3 Resistance layer

1. A laminated film comprising:
an insulating substrate resin film and a resistance layer in order in a thickness direction, wherein
the resistance layer includes chromium nitride, and
a temperature coefficient of resistance of the resistance layer is −400 ppm/° C. or more and −200 ppm/° C. or less.

2. The laminated film according to claim 1, wherein
the resistance layer has a body-centered cubic lattice structure.

3. The laminated film according to claim 1, wherein
the resistance layer does not have a A15-type structure.

4. The laminated film according to claim 1, wherein
parts by mole of nitrogen atoms with respect to 100 parts by mole of chromium atoms is 3.0 parts by mole or more and below 9 parts by mole in the chromium nitride.

5. The laminated film according to claim 1, wherein
a thickness of the resistance layer is 10 nm or more and 150 nm or less.

6. The laminated film according to claim 1, wherein
a thickness of the substrate resin film is 10 μm or more and 200 μm or less.

7. The laminated film according to claim 1, wherein
a material for the substrate resin film is polyimide.

8. A method for producing a second laminated film comprising:
a preparation step of preparing the laminated film according to claim 1 and
a heating step of heating the laminated film at 200° C. or less.

9. The method for producing a second laminated film according to claim 8, wherein
in the heating step, a temperature coefficient of resistance of the resistance layer after heating is set at −100 ppm/° C. or more and 100 ppm/° C. or less.

10. A method for producing a strain sensor comprising:
a preparation step of preparing the laminated film according to claim 1,
a heating step of heating the laminated film at 200° C. or less, and
a patterning step of patterning the resistance layer in the laminated film.
